(19) United States
(12) Patent Application Publication
(10) Pub. No.: US 2026/0297980 A1
(43) Pub. Date: Oct. 1, 2026

(54) STORAGE APPARATUS

(71) Applicant: Maxell, Ltd., Kyoto (JP)

(72) Inventors: Kazuo SHIKITA, Otokuni-gun, Kyoto (JP); Takuya SHIMIZU, Otokuni-gun, Kyoto (JP); Shuji NAGATOMI, Otokuni-gun, Kyoto (JP)

(21) Appl. No.: 18/996,330

(22) PCT Filed: Apr. 7, 2023
(86) PCT No.: PCT/JP2023/014374

§ 371 Date: Jan. 17, 2025

(30) Foreign Application Priority Data
Aug. 8, 2022 (JP) 2022-126518

(51) Int. Cl. E05B 47/00; E05B 65/00; H05K 5/02

(52) U.S. Cl. CPC E05B 47/0001; E05B 65/0075; H05K 5/0221

(57) ABSTRACT

A storage apparatus storing stockpile goods includes a storage cabinet, an electric lock locks and unlocks the storage cabinet, a power circuitry supplied with power by an external power source, a communication unit communicates with external apparatus, and a controller. The controller controls locking and unlocking of the electric lock, based on one or more of, information received by communication via the communication unit, power supply state from an external power source supplied to the power circuitry, and a communication state of the communication unit.

### TECHNICAL FIELD

The invention relates to a storage apparatus.

### BACKGROUND ART

Stockpile goods are being stored in preparation for future disasters. Patent Literature 1 discloses a pantry that can store emergency supplies such as emergency foodstuffs and emergency equipment, and can withstand use in an emergency. Specifically, Patent Literature 1 discloses, “a pantry for storing food and the like, with the stored items being taken in and out by opening and closing the door, the pantry is configured to an emergency food storage space having a capacity to store only enough emergency food supplies for a family comprising a predetermined composition to spend a predetermined number of days, an emergency equipment storage space can store emergency equipment other than emergency food supplies, and emergency lighting with motion sensor can see stored items even during a power outage, wherein the door is provided with an earthquake-resistant mechanism keeps the doors closed during an earthquake and prevents stored items from scattering, and it is provided also with a drawer locking mechanism to prevent drawers from popping out by locking during an earthquake, and/or with a fall prevention mechanism to prevent stored items from falling off shelf during an earthquake”.

### CITATION LIST

### Patent Literature

PTL 1: JP 2007-98052 A

### SUMMARY OF INVENTION

### Technical Problem

In the storage of stockpile goods, during normal time, it is necessary to be locked for security reasons. And, in an emergency, it is necessary to open the lock in order to use the stockpile goods. Therefore, the purpose of the invention is to provide a control that enables locking during normal times and unlocking during emergencies, in storage of stockpile goods.

### Solution to Problem

According to the invention, a storage apparatus storing stockpile goods is provided. This storage apparatus is configured to a storage cabinet, an electric lock locks and unlocks the storage cabinet, a power circuitry supplied with power by an external power source, a communication unit communicates with external apparatus, and a controller. And, the controller controls locking and unlocking of the electric lock, based on one or more of, information received by communication via the communication unit, power supply state from an external power source supplied to the power circuitry, and a communication state the communication unit.

### Advantageous Effects of Invention

According to the invention, in the storage of stockpile goods, a control is realized that enables locking during normal times and opening during emergencies. Note that, purpose, configuration, and effect other than those described above will be clarified in the description of the following embodiments of the invention.

### BRIEF DESCRIPTION OF DRAWINGS

FIG. 1 is a diagram illustrating an example of the overall system configuration.

FIG. 2 is a diagram illustrating an example of configuration of storage apparatus.

### DESCRIPTION OF EMBODIMENTS

Hereinafter, embodiments of the invention are described with reference to the drawings. The embodiments are illustrative examples to explain the invention, and have been omitted and simplified as appropriate for the sake of clarity of explanation. The invention can also be implemented in various other forms. Unless specifically limited, each constituent element may be singular or plural.

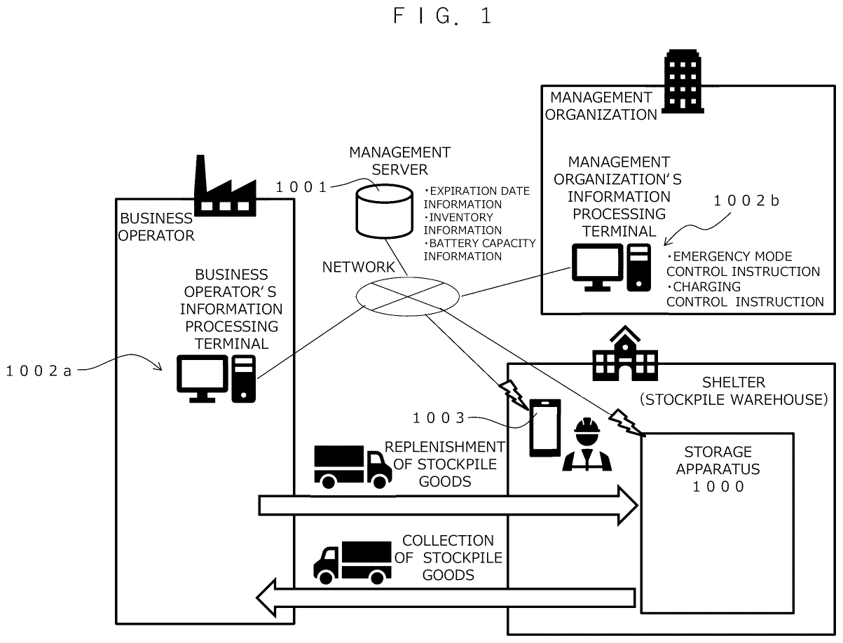

First, with reference to FIG. 1, an example of a system is configured to a storage apparatus 1000 will be described. As shown in FIG. 1, this system is configured to a storage apparatus 1000, a management server 1001, and information processing terminals (1002a, 1002b), and each of them is connected via a network.

The storage apparatus 1000 stores stockpile goods against disasters and is located in an appropriate shelter (e. g., a school or hospital with a stockpile warehouse) in the event of a disaster. The storage apparatus 1000 stores various items as stockpile goods, and, for example, stores batteries. Management server 1001 manages various information in the system. Management server 1001, as information about stockpile goods, for example, manages expiration date information, inventory information, battery capacity information, etc. Then, business operator and management organization can utilize the information managed by the management server 1001 in their work.

The information processing terminal 1002A is used by a business operator. Here, the business operator is a supplier of disaster stockpile goods, etc. The business operator can use the information processing terminal 1002a to obtain information from the management server 1001 and take appropriate actions.

The business operator, for example, replenishes stockpile batteries before their expiration date, and takes action to collect and recycle stockpile batteries near their expiration date. Here, the business operator may control the operation of the storage apparatus 1000 using the information processing terminal 1002a. Also, the business operator may use the information processing terminal 1002A to update the information on the management server 1001 with the latest information of after the working is completed. Note that, similar processing may be performed using a communication terminal 1003 carried by a worker on-site and connected to a network. Also, the management server 1001 may manage information related to work, etc., such as initial settings at the time Of installation of the storage apparatus 1000, settings at the time of maintenance, and replenishment/retrieval information.

The information processing terminal 1002B is used by a management organization. Here, the management organization is, an organization that manages evacuation shelters such as school and hospital, for example, a local government, medical institution management organization, etc. The management organization uses the information processing terminal 1002b to respond to the storage apparatus 1000 as appropriate.

The management organization, for example, in emergencies such as occurring disaster, responds to change the settings of the storage apparatus 1000 using the information processing terminal 1002b. Also, the management organization, for example, takes actions to instruct the charging control of the storage apparatus using the information processing terminal 1002b.

Each information processing terminal (1002a, 1002b) may access the storage apparatus 1000 via the network and management server 1001. On the other hand, it may access the storage apparatus 1000 via the network, without via the management server 1001. Also, the communication terminal 1003 held by the worker of business operator, may communicate directly with the storage apparatus 1000 without via the network.

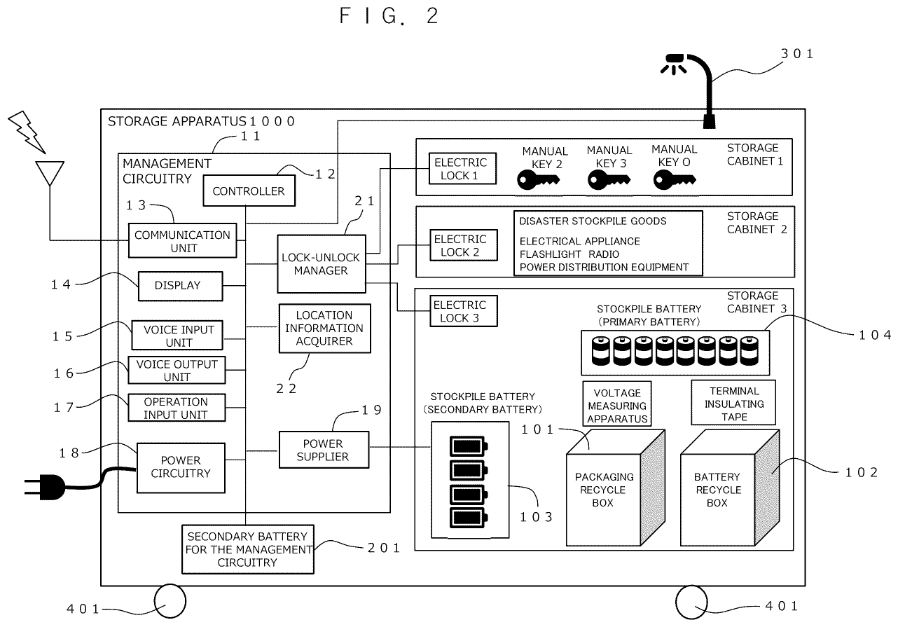

Next, an example configuration of a storage apparatus will be described with reference to FIG. 2. As shown in FIG. 2, the storage apparatus 1000 is configured to a plurality of storage cabinets (1 to 3) capable of storing items such as stockpile goods, and a management circuitry 11. Note that, the storage apparatus 1000, as an example, may be a housing structure with each of the opening and closing doors of each of the storage cabinets on the front side.

Storage cabinet 1 stores the manual key of other storage cabinets, in this example, the manual key 2 of storage cabinet 2 and the manual key 3 of storage cabinet 3. Here, the open/close door of storage cabinet 1 is locked/unlocked by electric lock 1 electrically connected to management circuitry 11.

Storage cabinet 2 stores disaster stockpile goods (in the example in FIG. 2, electrical appliances, flashlights, radios, and power distribution equipment). Here, the open/close door of storage cabinet 2 is locked/unlocked by electric lock 2 electrically connected to management circuitry 11. In addition, apart from the case of electric lock 2, the open/close door of the storage cabinet 2 can also be locked/unlocked by using the manual lock 2 stored in the storage cabinet 1.

Storage cabinet 3 stores primary battery and secondary battery as stockpile battery, voltage measuring apparatus, terminal insulating tape, packaging recycle box 101, and battery recycle box 102. Here, the open/close door of the storage cabinet 3 is locked/unlocked by the electric lock 3 electrically connected to the management circuitry 11. In addition, apart from the case of electric lock 3, the open/close door of the storage cabinet 3 can also be locked/unlocked by using the manual lock 3 stored in the storage cabinet 1.

Secondary battery to be stored in the storage cabinet 3 is placed in the secondary battery placement unit 103 which is electrically connected to the management circuitry 11, and secondary battery placed in the secondary battery placement unit 103 can be supplied (charged) by the management circuitry 11.

The voltage measuring apparatus, terminal insulating tape, packaging recycle box 101, and battery recycle box 102 are used by workers who replenish/retrieve stockpile batteries. stockpile batteries (primary batteries) are stored with terminal insulating tape attached to the electrode terminals by a worker. The worker measures the voltage of the stockpile battery (primary battery) with a voltage measuring apparatus, and places the stockpile battery (primary battery) that does not reach the specified threshold into the battery recycle box 102 as target for recycling. Also, the worker places packaging of stockpile batteries into the packaging recycle box 101 as target for recycling. In this way, by storing the recycle boxes (101, 102) in advance in the storage cabinet 3, during work, it can easily separate and collect the batteries and packaging to be recycled.

The management circuitry 11 is connected to the electric lock of each storage cabinet and performs electrical control. The management circuitry 11 is configured to a controller 12, communication unit 13, display 14 voice input unit 15, voice output unit 16, operation input unit 17, power circuitry 18, and power Supplier 19. Also, The management circuitry 11 is configured to a lock-unlock manager 21 and a location information acquirer 22. Also, the management circuitry 11 is configured to a storage (not shown) storing data used for data processing.

Controller 12 is the main unit that performs the prescribed processing and is composed of a suitable processor. Controller 12 is, for example, composed of a CPU (Central Processing Unit) but may also be composed of other semiconductor devices. Communication unit 13 is used for communication. In this embodiment, communication unit 13 is configured using a wireless communication interface. Display 14 is used for presenting appropriate information and is configured using an appropriate display. Display 14 may, as an example, be provided on an outer side of storage apparatus 100. Voice input unit 15 is used for voice input operation and, for example, is configured using a microphone. Voice output unit 16 is used for voice output and, for example, is configured using a speaker. Operation input unit 17 is configured to be used for appropriate input operations such as buttons and a touch panel. Power circuitry 18 is a circuit used to supply electric power, and electric power is supplied from outside the storage apparatus 1000 to the management circuitry 11 via the power circuitry 18. Note that, as an example, the external power is supplied via an electrical outlet. Power supplier 19 is configured as a circuit used to supply power.

The lock-unlock manager 21 is configured as an electric circuitry connected to each electric lock and is used to lock/unlock each electric lock. The location information acquirer 22 acquires location information of the storage apparatus 1000 and, for example, can be configured using a GPS receiver.

The storage stores data using for data processing as appropriate and is configured to a main memory apparatus and an auxiliary memory apparatus. The main memory apparatus is an apparatus temporarily stores data when controller 12 performs data processing and, for example, is configured using RAM (Random Access Memory). The auxiliary memory apparatus is an apparatus that stores data such as programs that realize the operation of the management circuitry 11 and, for example, is configured using hard disk drive (HDD).

The storage apparatus 1000 is configured to a secondary battery for the management circuitry 201. The secondary battery for the management circuitry 201 is used as an auxiliary power source for the management circuitry 11, for example, to supply power to the management circuitry 11 in the absence of power from the power circuitry 18.

The storage apparatus 1000 is configured to a lighting unit 301. The lighting unit 301 may be installed on the upper side of the storage apparatus, for example, to illuminate the opening and closing door of the storage cabinet. By this, it is possible to grasp the position of the open/close door and easily move equipment in and out of the storage apparatus, even in a dark environment such as at night. Note that, the lighting may be provided at other locations, such as inside the storage apparatus.

Also, the storage apparatus 1000 may be configured to a wheel 401 at the bottom to facilitate movement, taking into account installation work and rearrangement at the shelter.

During normal time, external power is supplied from the power circuitry 18 and the storage apparatus 1000 stores the items in the storage cabinet with each electric lock locked. Next, the various control examples that enable the opening of the locks in an emergency will be described in detail.

### Example of Control Without External Power Input

The storage apparatus 1000 (in detail, controller 12) switches the power supply to the secondary battery for the management circuitry 201, when the power supply from the power circuitry 18 is lost due to a disaster etc. Then, controller 12 performs a determination based on the state and/or the time of use of secondary battery for the management circuitry 201 and, based on the determination result, performs a control of the opening of the electric lock. As a specific example, controller 12 may determine whether the remaining battery capacity of the secondary battery for the management circuitry 201 is the predetermined remaining battery capacity, and open all or some of the electric locks when the predetermined remaining battery capacity is reached. Also, the controller 12 may determine, based on the timeout perspective, whether a predetermined amount of time has elapsed since switching the power supply, and may open all or some of the electric locks when the predetermined amount of time has elapsed. Note that, some electric locks include, for example, the electric lock of a storage cabinet that is pre-set to be opened in this control. Some electric locks may include, for example, an electric lock of a storage cabinet where a manual key is stored.

Note that, controller 12 maintains communication even after switching the power supply. Then, The controller 12 performs to process that sending appropriate information, such as information about the switch to the secondary battery for the management circuitry 201 (i.e., the power source used) , information about the locking/unlocking status of the electric lock, to the management server 1001 and/or the information processing terminal (1002b) of the management organization.

### Examples of Control in Emergency (e.g., Disaster)

The storage apparatus 1000 (in detail, controller 12), for example, performs the following controls in the emergency such as occurring disaster.

As a first example, if the settings of storage apparatus 1000 are changed by the management organization and storage apparatus 1000 is set to emergency mode, controller 12 performs control corresponding to the emergency mode. Note that, the emergency mode is a mode in which the conditions for opening the lock are relaxed compared to the usual time (normal time) mode. In the emergency mode, for example, a person other than the person in manage of the storage apparatus 1000, can open the electric lock by input operation alone, without the need for communication. In contrast, in the usual times, the electric lock cannot be opened only by an input operation by anyone other than the person who manages the storage apparatus 1000.

In emergency mode, the lock can be opened by appropriate input operations. storage apparatus 1000 may, for example, be provided with an emergency button. That is, operation input unit 17 may include an emergency button. When this emergency button is pressed, controller 12 may open the electric lock. Also, for example, the microphone of voice input unit 15 may be used, and controller 12 may open the electric lock based on the result of voice recognition.

As a second example, when the emergency mode is set as above, controller 12 performs the control corresponding to the emergency mode. Then, by input operation, controller 12 unlocks only the electric lock of the storage cabinet where the manual key is stored. Therefore, it is possible to take out the manual keys of other storage cabinets and open the locks using the manual keys. Note that, in the same way as described above, the lock can be opened by appropriate input operation such as using the emergency button.

As a third example, controller 12 performs control corresponding to the emergency mode when set to the emergency mode as described above. In this example, the controller 12, first, communicates with the information processing terminal 1002b of the management organization by input operation such as pressing an emergency button. Then, when permission to open the lock is output from the information processing terminal 1002b of the management organization, controller 12 opens the electric lock. In other words, the controller opens the lock via communication.

Note that, for example, using voice input unit 15 and voice output unit 16, etc., it may be confirmed situation of a conversation between the person in the management organization and the input operator etc. On the other hand, the conversation between the management organization and the input operator may be omitted and permission to open the lock may be output.

Also, the controller 12 may open all the electric locks or only the electric lock of a specific storage cabinet. controller 12 may open only the electric lock of the preset storage cabinet that stores the manual key.

As a fourth example, controller 12 may determine whether or not it is an emergency based on communication status, and process based on the results of that determination. If it is determined that communication is not possible, controller 12 may shift to emergency mode without the management organization's decision, relax conditions of open the lock. And, the controller 12 may open the electric lock in response to the same input operation as above, such as using the emergency button.

The storage apparatus 1000 may be configured to a camera and may monitor the input operator in the above 1 to 4 examples. Then, the storage apparatus 1000 may store the image data captured by the camera in storage, and, if communication is available, transmit the image data to the management server 1001 and/or the information processing terminal 1002b of the management organization. Also, the storage apparatus 1000 may store the input operations in the storage as an operation log. Then, the storage apparatus 1000 may transmit the operation log to the management server 1001 and/or the information processing terminal 1002b of the management organization, in the same manner, if it is in a communication enabled state.

### Example of Control in Communication State

The storage apparatus 1000 (in detail, controller 12), for example, from the viewpoint of communication status, may also perform the following controls.

As a first example, controller 12 determines whether communication is possible, and if it determines that communication is not possible, it may open all electric locks.

As a second example, controller 12 may open all electric locks, if it determines that communication is not possible and that there is no power supply through power circuitry 18 from an external power source.

As a third example, controller 12 may determine whether communication is possible, and if it determines that communication is not possible, it may open only electric lock of some storage cabinet (e.g., electric lock of preset storage cabinet).

As a fourth example, controller 12 may open only electric lock of some storage cabinet (e.g., electric lock of preset storage cabinet), if it determines that communication is not possible and that there is no power supply through power circuitry 18 from an external power source.

Various control examples were described, but the following controls may be performed. Also, the following modifications may be made.

The storage apparatus 1000 may be provided with a sensor to detect the opening and closing of the opening and closing door of the storage cabinet. And, the storage apparatus 1000 may transmit the information about the opening and closing of the opening and closing door of the storage cabinet to the management server 1001 and/or the information processing terminal (1002a, 1002b). Also, in the event of an emergency, this information about the opening and closing of the opening and closing door may be stored in the storage, and if communication is possible, it may transmit to the management server 1001 and/or the information processing terminal (1002a, 1002b).

At the time of work such as moving or installing the storage apparatus 1000, the electric lock may be opened by the control described above when the power supply through the power circuitry 18 from the external power source is no longer available. Therefore, the storage apparatus 1000 (in detail, controller 12) may perform control to change to the working mode. Here, the working mode is a mode in which the above-mentioned control to open the lock is not performed. In other words, the work mode is a mode in which the electric lock is kept locked. After the work, the mode may be changed from the working mode to the normal mode, and the above control to open the lock may be performed. In this way, by switching the work mode on and off, the electric lock can be prevented from opening during work, and appropriate control can be performed during usual time.

Note that, the change of work mode may be performed, for example, based on an output from the information processing terminal 1002A of the business operator. Also, it may be performed based on an output from the communication terminal 1003 of the worker. Also, it may be executed based on input from the operation input unit 17 of the storage apparatus 1000. Also, in the work mode change process, authentication such as password authentication may be requested, and the process may be executed based on the result of the authentication.

When supplying power to the stored secondary battery via power supplier 19, controller 12 may supply power to the secondary battery while power is being supplied from the external power source via power circuitry 18. On the other hand, controller 12 may control not to supply power to the secondary battery when power is not supplied via power circuitry 18 from an external power source. Also, controller 12 may control supplying power from the stored secondary battery to the management circuitry 11 via the power supplier 19 in an emergency. Here, controller 12 may, for example, determine the timing when the remaining battery charge of the secondary battery for the management circuitry 201 falls below the predetermined remaining battery charge, or when the predetermined time has elapsed since the secondary battery for the management circuitry 201 was used, as the time of emergency.

In the lock-opening permission control using the information processing terminal 1002B of the management organization, information specifying the electric lock to be opened is output from the information processing terminal 1002B, and controller 12 may open the specified electric lock.

The display 14 may, as an example, present information by electronic paper. In this case, since the power consumption during the display is smaller, the last display state can be maintained, even when the power supply from the secondary battery for the management circuitry 201 is lost.

A storage cabinet storing stockpile battery (primary battery), may be provided with a primary battery housing unit 104 with separate replenishment and take-out ports for the primary battery, so that the primary battery nearing its expiration date can be supplied first. The primary battery housing unit 104 can be configured, as an example, as box-shaped housing with a replenishment port at the top front and a take-out port at the bottom front. Also, the stockpile battery (secondary battery) may be provided with an information storage (e.g., RFID tag). Then, in the information storage, it may write information about the battery life, such as the number of times the battery has been recharged, the date and time of recharging, etc. In other words, the information storage may store information about the history of recharging. The information stored in the information storage may be referred to by the worker, it is possible to facilitate maintenance and battery replacement work.

When communication unit 13 receives information on the expected occurrence of a disaster (e.g., weather information such as typhoons, heavy rain, etc.) in advance, controller 12 may control the charging rate of the stockpile battery (secondary battery) to be increased from the usual time (normal time), from before the expected date of the disaster (e.g., one day to three days before). Controller 12, for example, may charge the secondary battery aiming at a rate of 70% under usual time, and charge the secondary battery aiming at a rate of 80 to 90% when it receives the disaster forecast information.

Also, the information processing terminal 1002b of the management organization may send a command to increase the secondary battery charging rate to the storage apparatus 1000 installed in the area where a disaster is expected. Then, controller 12 may recharge the battery based on the command of the information processing terminal 1002b and increase the recharge rate of the secondary battery.

When it switches to emergency mode during a disaster, and power is supplied from an external power source via power circuitry 18, controller 12 may control to increase the charge rate of the stockpile battery (secondary battery). Controller 12 may control a change from the normal charging mode to the rapid charging mode, which performs rapid charging by increasing the charging current or the like.

Also, storage apparatus 1000 installed in areas neighboring areas where a disaster is predicted (or where a disaster has occurred), in the same way as storage apparatus 1000 installed in areas where a disaster is predicted (or where a disaster has occurred), may control changing the charging rate, and changing to rapid charging mode, etc. Then, the storage apparatus 1000 in the neighboring area may be delivered to the area where the disaster occurred. By this, in the area where the disaster occurred, it enables the use of secondary batteries with a high recharge rate stored in the storage apparatus 1000 delivered from the neighboring area.

Note that, storage apparatus 1000 in neighboring areas, based on commands from the information processing terminal 1002b of the management organization, may control to change charging. Also, the storage apparatus 1000, via the network and communication unit 13, may obtain information on the status of charging other storage apparatus 1000, and location information of the storage apparatus 1000 installed in other areas, determines whether it is neighboring area of area installed the storage apparatus 1000 changed charging, and controls to change charging. Here, whether or not the area corresponds to a neighboring area, for example, may be determined based on the distance based on the location information of each storage apparatus 1000, if the distance between the storage apparatuses 1000 based on the location information is equal to or less than a predetermined distance, it may be determined that it is applicable to in a neighboring area.

Although the embodiments of the invention have been described in detail above, the invention is not limited to the aforementioned embodiments, and various design changes can be made to the extent that the spirit of the invention described in the claims is not departed from. For example, the aforementioned embodiments are described in detail for the purpose of explaining the invention in an easy-to-understand manner, and are not necessarily limited to those having all the described configurations. It is also possible to replace some of the configurations of one embodiment with configurations of other embodiments, and it is also possible to add configurations of other embodiments to the configurations of one embodiment. Furthermore, regarding some of the configurations of each embodiment, it is possible to add, delete, or replace other configurations.

The business operator may operate to renew stockpile supplies by replacing the storage apparatus 1000 itself. In addition, regarding supplies that are different from stockpile batteries, the worker of business operator may also replenish disaster stockpile supplies stored in the storage apparatus 1000 cabinets, and an operation may be implemented in which the worker of business operator collects the equipment according to the expiration date.

Primary batteries to be stockpiled include, for example, dry cell, coin cell, and button cell batteries. Also, Secondary batteries to be stockpiled include, for example, all-individual batteries, secondary batteries, and batteries with portable terminals.

The installation of the storage apparatus 1000 may be performed by workers of the business operator. On the other hand, it may be installed by shelter staff or others after delivery by a delivery company.

### REFERENCE SIGNS LIST

11 management circuitry
12 controller
13 communication unit
14 display
15 voice input unit
16 voice output unit
17 operation input unit
18 power circuitry
19 power supplier
21 lock-unlock manager
22 location information acquirer
101 packaging recycle box
102 battery recycle box
103 secondary battery placement unit
104 primary battery housing unit
201 secondary battery for the management circuitry (secondary battery for the management)
301 lighting unit
401 wheel
1000 storage apparatus
1001 management server
1002a information processing terminal
1002b information processing terminal
1003 communication terminal

1. A storage apparatus storing stockpile goods comprising:
a storage cabinet;
an electric lock locks and unlocks the storage cabinet;
a power circuitry supplied with power by an external power source;
a communication unit communicates with external apparatus; and
a controller,
wherein the controller controls locking and unlocking of the electric lock, based on one 4 more of, information received by communication via the communication unit, power supply state from an external power source supplied to the power circuitry, and a communication state of the communication unit.

2. The storage apparatus according to claim 1, further comprising:
a secondary battery for the management supplying power for the operation of the controller and the communication unit,
wherein after the controller and the communication unit are operated by the power supply from the external power source supplied to the power circuitry, when power supply from external power source to the power circuitry is cut off, power for the operation of the controller and the communication unit is supplied from a secondary battery for the management, and when a predetermined condition is subsequently satisfied, the controller controls the unlocking of the electronic lock.

3. The storage apparatus according to claim 2,
wherein the predetermined condition is whether or not the remaining battery charge of the secondary battery for the management supplies power for operation of the controller and the communication unit, has fallen below a predetermined value.

4. The storage apparatus according to claim 2,
wherein the predetermined condition is whether or not a predetermined time has elapsed since the power for operating the controller and the communication unit has been supplied from the secondary battery for the management.

5. The storage apparatus according to claim 2,
wherein the predetermined condition is whether or not the communication state of the communication unit has become communication disabled.

6. The storage apparatus according to claim 1,
wherein when the communication unit receives information indicating an emergency from external apparatus via communication, the controller performs control to change the conditions for unlocking the electronic lock so as to relax condition.

7. The storage apparatus according to claim 1,
wherein the controller controls the electronic lock to be unlocked when the communication state of the communication unit becomes communication disabled.

8. The storage apparatus according to claim 1,
wherein when information indicating a predicted occurrence of a disaster is received via the communication unit, controller performs control to increase the charging rate of the stored secondary battery.

9. The storage apparatus according to claim 1,
wherein the controller acquires the charging status and location information of storage apparatuses installed at different locations via the communication unit, and performs control to increase the charging rate of the stored secondary battery, based on the acquired charging status of storage apparatus and distance to the storage apparatus where location information was acquired.

10. The storage apparatus according to claim 1,
wherein it stores a secondary battery with an information storage stores information regarding the charging history.

11. The storage apparatus according to claim 1,
wherein the controller changes, based on external input, from a mode for controlling the locking and unlocking of the electronic lock to a mode for maintaining the electronic lock in a locked state.

12. The storage apparatus according to claim 1, further comprising:
a power supplier is supplied with power from the stored secondary battery,
wherein the controller controls the power supplier to supply power from a stored secondary battery in the event of an emergency.

13. The storage apparatus according to claim 1,
wherein it houses a recycling box for separately collecting the packaging of batteries to be recycled and the secondary batteries to be recycled.

14. The storage apparatus according to claim 1, further comprising:
a camera monitors the input operator performing the input operation; and
a storage for storing image data acquired by the camera.

15. The storage apparatus according to claim 1, further comprising:
a sensor for detecting the opening and closing of the door of the storage cabinet; and
a storage for storing information acquired by the sensor.

16. A charging control method controls charging of secondary battery comprising:
a receiving step receiving information regarding a predicted disaster occurrence; and
a charge control step performing charge control different from usual time on the secondary battery before the predicted date and time of the disaster is acquired based on the information received in the receiving step.

17. The charging control method according to claim 16,
wherein the charge control step performs control to increase the charging rate of the secondary battery to higher than usual time before the predicted date and time of the disaster occurrence.

18. The charging control method according to claim 17,
wherein the information regarding a predicted disaster occurrence is weather information.
